(19) United States
(12) Patent Application Publication
(10) Pub. No.: US 2026/0165185 A1
(43) Pub. Date: Jun. 11, 2026

(54) FAN-OUT SEMICONDUCTOR PACKAGE

(71) Applicant: SAMSUNG ELECTRONICS CO., LTD., Suwon-si (KR)

(72) Inventors: Sangseok HONG, Suwon-si (KR); Jaeseong KIM, Suwon-si (KR); Jeongseok KIM, Suwon-si (KR); Taewook KIM, Suwon-si (KR); Yejin LEE, Suwon-si (KR); Jooyoung CHOI, Suwon-si (KR)

(73) Assignee: SAMSUNG ELECTRONICS CO., LTD., Suwon-si (KR)

(21) Appl. No.: 19/179,371

(22) Filed: Apr. 15, 2025

(30) Foreign Application Priority Data
Sep. 9, 2024 (KR) 10-2024-0122584

(51) Int. Cl. H10W 72/90; H10W 72/00; H10W 74/10

(52) U.S. Cl. CPC H10W 72/9415; H10W 72/823; H10W 74/111

(57) ABSTRACT

A semiconductor package includes a semiconductor chip, a molding layer at least partially surrounding the semiconductor chip, and a redistribution structure on the molding layer and including a redistribution pattern and a redistribution insulating layer at least partially surrounding the redistribution pattern. The redistribution pattern includes pads and metal layers disposed on the pads. The redistribution insulating layer includes an uppermost insulating layer at least partially surrounding the pads and the metal layers, and groove groups at least partially passing through the uppermost insulating layer. The groove groups at least partially overlap the pads in a vertical direction, respectively. Each of the groove groups includes a pad groove and a side groove. The pad groove at least partially overlaps at least one of the metal layers in the vertical direction. The side groove at least partially overlaps at least one of the pads in the vertical direction.

### CROSS-REFERENCE TO RELATED APPLICATIONS

This application claims benefit of priority under 35 U.S.C. § 119 to Korean Patent Application No. 10-2024-0122584, filed on Sep. 9, 2024, in the Korean Intellectual Property Office, the disclosure of which is incorporated by reference herein in its entirety.

### BACKGROUND

The present disclosure relates generally to semiconductor packages, and more particularly, to a fan-out semiconductor package.

A possible approach for improving a performance of a semiconductor package may include to increase the number of external connection terminals of the semiconductor package. An increase in the number of external connection terminals may result in a need to secure a sufficient planar area of the semiconductor package. However, a need to reduce manufacturing costs of the semiconductor package may be addressed by reducing the planar area of the semiconductor chip. To potentially address these seemingly competing approaches, a fan-out package may have been developed a semiconductor chip may be connected to external connection terminals by using a connection structure that may have a planar area that may be greater than the planar area of the semiconductor chip. Such a configuration may provide a semiconductor package with a semiconductor chip with a reduced size while potentially securing a sufficient planar area of the semiconductor package for an increased number of external connection terminals.

### SUMMARY

One or more example embodiments of the present disclosure provide a semiconductor package suppressing short circuits between connection terminals.

According to an aspect of the present disclosure, a semiconductor package includes a semiconductor chip, a molding layer at least partially surrounding the semiconductor chip, and a redistribution structure on the molding layer and including a redistribution pattern and a redistribution insulating layer at least partially surrounding the redistribution pattern. The redistribution pattern includes pads and metal layers disposed on the pads. The redistribution insulating layer includes an uppermost insulating layer at least partially surrounding the pads and the metal layers, and groove groups at least partially passing through the uppermost insulating layer. The groove groups at least partially overlap the pads in a vertical direction, respectively. Each of the groove groups includes a pad groove and a side groove. The pad groove at least partially overlaps at least one of the metal layers in the vertical direction. The side groove at least partially overlaps at least one of the pads in the vertical direction.

According to an aspect of the present disclosure, a semiconductor package includes a first semiconductor package, a second semiconductor package stacked on the first semiconductor package, and connection terminals between the first semiconductor package and the second semiconductor package. The first semiconductor package includes a lower redistribution structure, a first semiconductor chip disposed on the lower redistribution structure, a first molding layer on the lower redistribution structure and at least partially surrounding the first semiconductor chip, an upper redistribution structure on the first molding layer, and a connection structure passing through the first molding layer and electrically coupling the lower redistribution structure with the upper redistribution structure. The upper redistribution structure includes an upper redistribution pattern including upper pads and metal layers positioned on the upper pads, and an upper redistribution insulating layer including an uppermost insulating layer at least partially surrounding the upper pads and the metal layers. The uppermost insulating layer includes groove groups passing through at least part of the uppermost insulating layer and at least partially overlapping the upper pads and the metal layers in a vertical direction. Each of the groove groups includes a side groove at least partially overlapping at least one of the upper pads, and a pad groove at least partially overlapping at least one of the metal layers. Each of the connection terminals is disposed in the pad groove and the side groove of each of the groove groups.

According to an aspect of the present disclosure, a semiconductor package includes a first semiconductor package, a second semiconductor package stacked on the first semiconductor package, and connection terminals positioned between the first semiconductor package and the second semiconductor package. The first semiconductor package includes a lower redistribution structure, a first semiconductor chip disposed on the lower redistribution structure, a first molding layer on the lower redistribution structure and at least partially surrounding the first semiconductor chip, an upper redistribution structure on the first molding layer, and a connection structure passing through the first molding layer and electrically coupling the lower redistribution structure with the upper redistribution structure. Each of the connection terminals includes a pad protrusion and a side protrusion. The upper redistribution structure of the first semiconductor package includes an upper redistribution pattern including upper pads and metal layers positioned on the upper pads, and an upper redistribution insulating layer including an uppermost insulating layer at least partially surrounding the upper pads and the metal layers. The pad protrusion of each of the connection terminals passes through the uppermost insulating layer and is in contact with at least one of the upper pads. The side protrusion of each of the connection terminals passes through the uppermost insulating layer and is in contact with at least one of the metal layers. A vertical level of a bottom surface of the side protrusion of each of the connection terminals is lower than a vertical level of a bottom surface of the pad protrusion of each of the connection terminals.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a plan view schematically illustrating a semiconductor package, according to embodiments;

FIG. 2 is a cross-sectional view schematically illustrating the semiconductor package of FIG. 1 taken along line A-A′ of FIG. 1, according to embodiments;

FIG. 3 is an enlarged view schematically illustrating the semiconductor package of FIG. 2, showing an enlarged portion EX1 of FIG. 2, according to embodiments;

FIG. 4 is a cross-sectional view schematically illustrating a semiconductor package in which a portion is cut away, according to embodiments;

FIG. 5 is a plan view illustrating a portion of a semiconductor package, according to embodiments;

FIG. 6 is a plan view illustrating a portion of a semiconductor package, according to embodiments;

FIG. 7 is a plan view illustrating a portion of a semiconductor package, according to embodiments;

FIG. 8 is a plan view illustrating a portion of a semiconductor package, according to embodiments;

FIG. 9 is a plan view schematically illustrating a semiconductor package, according to embodiments;

FIG. 10 is a plan view schematically illustrating a semiconductor package, according to embodiments;

FIG. 11 is a cross-sectional view schematically illustrating a semiconductor package in which a portion is cut away, according to embodiments; and

FIG. 12 is an enlarged view schematically illustrating the semiconductor package of FIG. 11, showing an enlarged portion EX2 of FIG. 11, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, however, these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements however the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

In the present disclosure, the articles “a” and “an” are intended to include one or more items, and may be used interchangeably with “one or more.” Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, however do not necessarily, all refer to the same embodiment. The embodiments described herein are example embodiments, and thus, the disclosure is not limited thereto and may be realized in various other forms.

As used herein, each of the terms “GaAs”, “InAs”, “InP”, “SiC”, or the like may refer to a material made of elements included in each of the terms and is not a chemical formula representing a stoichiometric relationship.

Hereinafter, various embodiments of the present disclosure are described with reference to the accompanying drawings.

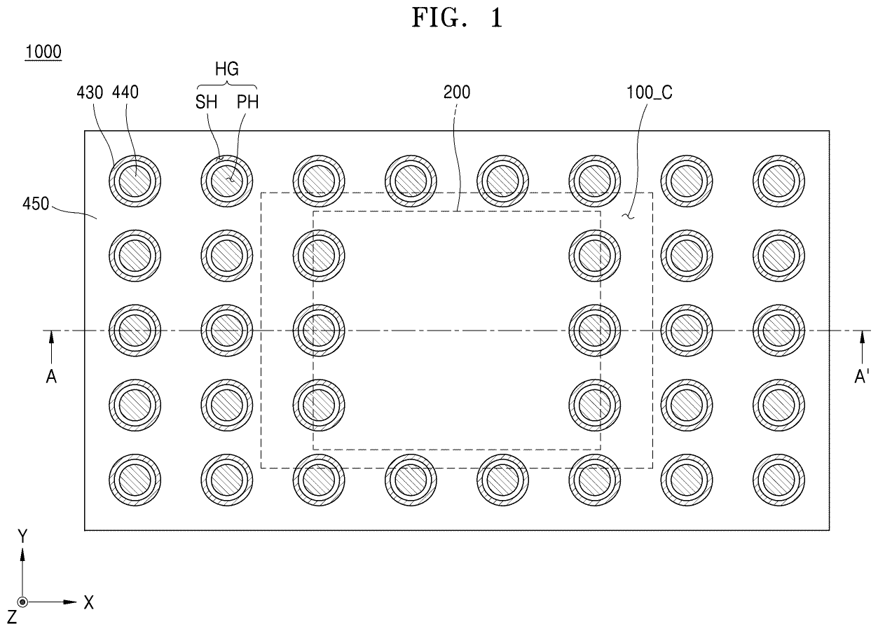

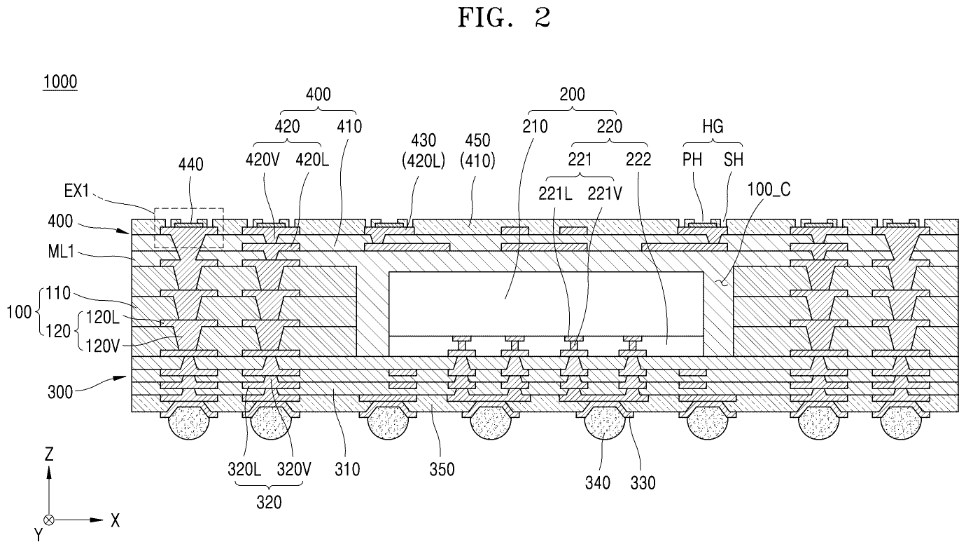

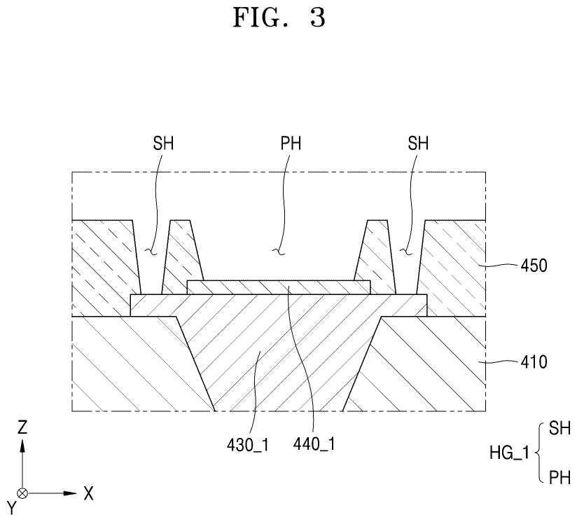

FIG. 1 is a plan view schematically illustrating a semiconductor package 1000, according to embodiments. FIG. 2 is a cross-sectional view schematically illustrating the semiconductor package 1000 of FIG. 1 taken along line A-A′ of FIG. 1. FIG. 3 is an enlarged view schematically illustrating the semiconductor package 1000 of FIG. 2 by enlarging the portion EX1 of FIG. 2.

Referring to FIGS. 1 to 3, the semiconductor package 1000 may include a lower redistribution structure 300, a connection structure 100, a first semiconductor chip 200, a first molding layer ML1, and an upper redistribution structure 400.

As used herein, a direction parallel to a top surface of the lower redistribution structure 300 may be referred to as a first horizontal direction (X direction), a direction perpendicular to the top surface of the lower redistribution structure 300 may be referred to as a vertical direction (Z direction), and a direction perpendicular to the first horizontal direction (X direction) and the vertical direction (Z direction) may be referred to as a second horizontal direction (Y direction). The horizontal direction may be referred to as a direction obtained by combining the first horizontal direction (X direction) with the second horizontal direction (Y direction).

The connection structure 100 may be arranged on the lower redistribution structure 300. For example, the connection structure 100 may be electrically connected to a lower redistribution pattern 320 of the lower redistribution structure 300. The connection structure 100 may electrically connect the upper redistribution structure 400 to the lower redistribution structure 300.

The connection structure 100 may include a cavity 100_C extending from a top surface to a bottom surface. The first semiconductor chip 200 may be mounted in the cavity 100_C of the connection structure 100. The cavity 100_C may be formed in the center of the connection structure 100 as illustrated in FIG. 1. However, the number and arrangement of cavities 100_C are not limited thereto.

The connection structure 100 may include a plurality of base layers 110 and a via structure 120. In some embodiments, the plurality of base layers 110 may include first to third base layers stacked in the vertical direction (Z direction). For example, the connection structure 100 may have a multilayer structure including the first to third base layers. The plurality of base layers 110 may surround at least part of the via structure 120.

In some embodiments, each of the plurality of base layers 110 may include an insulating material in which a phenol resin, a thermosetting resin such as, but not limited to, an epoxy resin, a thermoplastic resin such as, but not limited to, polyimide, or at least one resin selected from the above resins is impregnated into a core material including an inorganic filler and/or glass fiber.

For example, each of the plurality of base layers 110 may include, but not be limited to, prepreg, an Ajinomoto build-up film (ABF), flame retardant 4 (FR4), tetrafunctional epoxy, polyphenylene ether, bismaleimide triazine (BT), epoxy/polyphenylene oxide, thermount, cyanate ester, polyimide, a liquid crystal polymer, or a combination thereof.

The via structure 120 may include a plurality of connection pads 120L and a plurality of connection vias 120V. The plurality of connection pads 120L may extend in a horizontal direction on a top surface or a bottom surface of each of the plurality of base layers 110.

In some embodiments, the plurality of connection pads 120L may include first to fourth connection pads at different vertical levels. For example, the first connection pads at the bottom of the plurality of connection pads 120L may be connected to the lower redistribution structure 300, and the fourth connection pads at the top of the plurality of connection pads 120L may be connected to the upper redistribution structure 400.

The plurality of connection vias 120V may extend in the vertical direction (Z direction) in the plurality of base layers 110. The plurality of connection vias 120V may connect the plurality of connection pads 120L at different vertical levels to each other. In some embodiments, the plurality of connection vias 120V may include first to third connection vias at different vertical levels.

In some embodiments, each of the plurality of connection pads 120L may include, but not be limited to, electrolytically deposited (ED) copper foil, rolled-annealed (RA) copper foil, stainless steel foil, aluminum foil, ultra-thin copper foil, sputtered copper, or a copper alloy. In some embodiments, each of the plurality of connection vias 120V may include copper (Cu), nickel (Ni), stainless steel, beryllium copper, or a combination thereof.

The first semiconductor chip 200 may be positioned on the lower redistribution structure 300. The first semiconductor chip 200 may be mounted in the cavity 100_C of the connection structure 100 and may be spaced apart from an internal wall of the cavity 100_C. Although FIG. 2 illustrates the semiconductor package 1000 as including one first semiconductor chip 200, the number of first semiconductor chips 200 is not limited thereto. In some embodiments, the first semiconductor chip 200 may be referred to as a lower semiconductor chip.

The first semiconductor chip 200 may include a first semiconductor substrate 210 and a first wiring structure 220. The first semiconductor substrate 210 may include an active surface and an inactive surface opposite thereto. The first wiring structure 220 may be formed on the active surface of the first semiconductor substrate 210.

The first semiconductor chip 200 may be arranged on the lower redistribution structure 300 such that the active surface thereof faces the lower redistribution structure 300 of the first semiconductor substrate 210. For example, the first semiconductor chip 200 may be arranged on the lower redistribution structure 300 in a face-down manner. In this case, the inactive surface of the first semiconductor chip 200 may be referred to as a top surface of the first semiconductor chip 200 or may be referred to as a bottom surface of the first semiconductor chip 200 of the first semiconductor substrate 210 opposite to the inactive surface of the first semiconductor chip 200.

The first semiconductor substrate 210 may include, for example, a semiconductor material such as silicon (Si) or germanium (Ge). Alternatively or additionally, the first semiconductor substrate 210 may include a compound semiconductor material such as, but not limited to, silicon carbide (SiC), gallium arsenide (GaAs), indium arsenide (InAs), or indium phosphide (InP). The first semiconductor substrate 210 may include a well doped with impurities as a conductive region. The first semiconductor substrate 210 may have various device isolation structures such as, but not limited to, a shallow trench isolation (STI) structure.

A plurality of various types of individual devices may be formed on the active surface of the first semiconductor substrate 210. The plurality of individual devices may be electrically connected to the first wiring structure 220. In addition, each of the plurality of individual devices may be electrically isolated from other adjacent individual devices by an insulating layer.

In some embodiments, the first semiconductor chip 200 may be and/or may include a logic device. For example, the first semiconductor chip 200 may be and/or may include a central processing unit (CPU) chip, a graphics processing unit (GPU) chip, an application processor (AP) chip, or the like. In other embodiments, when the semiconductor package includes a plurality of first semiconductor chips 200, at least one of the plurality of first semiconductor chips 200 may be and/or may include a CPU chip, a GPU chip, an AP chip, or the like. In some embodiments, the plurality of first semiconductor chips 200 may also include a memory semiconductor chip including a memory device.

For example, the memory device may be and/or may include a non-volatile memory device such as, but not limited to, flash memory, phase-change random access memory (PRAM), magneto-resistive random access memory (MRAM), ferroelectric random access memory (FeRAM), resistive random access memory (RRAM), or the like. In some embodiments, the memory device may be and/or may include a volatile memory device such as, but not limited to, dynamic random access memory (DRAM), static random access memory (SRAM), or the like.

The first wiring structure 220 of the first semiconductor chip 200 may include first wiring patterns 221 and a first wiring insulating layer 222 surrounding the first wiring patterns 221. Each of the first wiring patterns 221 may include a first wiring line 221L extending in the horizontal direction and a first wiring via 221V extending in the vertical direction (Z direction) from the first wiring line 221L. The first wiring patterns 221 may be electrically connected to the plurality of individual devices of the first semiconductor substrate 210.

In some embodiments, the first wiring structure 220 may have a multilayer wiring structure including the first wiring lines 221L and the first wiring vias 221V at different vertical levels. Some of the first wiring lines 221L of the first wiring patterns 221 of the first wiring structure 220 may be exposed to the outside. For example, portions of the first wiring lines 221L exposed to the outside may be referred to as first front pads.

The lower redistribution structure 300 may extend input/output (I/O) terminals of the first semiconductor chip 200 to an outer region of the first semiconductor chip 200. The lower redistribution structure 300 may include lower redistribution insulating layers 310, and lower redistribution patterns 320 each including lower redistribution vias 320V and lower redistribution lines 320L.

The number and arrangement of lower redistribution insulating layers 310, lower redistribution vias 320V, and lower redistribution lines 320L constituting the lower redistribution structure 300 are not limited to those illustrated in the drawings, and may be changed in various ways without departing from the scope of the present disclosure.

The lower redistribution insulating layers 310 may include an insulating material (e.g., a photoimagable dielectric (PID) resin). In this case, the lower redistribution insulating layers 310 may further include an inorganic filler. The lower redistribution insulating layers 310 may include the same material and/or different materials.

The lower redistribution pattern 320 including the lower redistribution vias 320V and the lower redistribution lines 320L may serve to extend the I/O terminals of the first semiconductor chip 200 to the outside. Each of the lower redistribution lines 320L may be arranged on at least one of top and bottom surfaces of each of the lower redistribution insulating layers 310 and may extend in the horizontal direction. The lower redistribution vias 320V may extend in the vertical direction (Z direction) through the lower redistribution insulating layers 310, and may be connected to parts of the lower redistribution lines 320L.

The lower redistribution via 320V may be completely filled with a conductive material, or may have a shape in which the conductive material is formed along a wall of the lower redistribution via 320V. The lower redistribution pattern 320 may include a conductive material, such as, but not limited to, copper (Cu), aluminum (Al), silver (Ag), tin (Sn), gold (Au), nickel (Ni), lead (Pb), titanium (Ti), or an alloy thereof.

The first wiring structure 220 of the first semiconductor chip 200 may directly contact top surfaces of the lower redistribution insulating layers 310. In some embodiments, the lower redistribution structure 300 may be formed on the bottom surface of the first semiconductor chip 200 by a chip-first process. According to the order in which the lower redistribution structure 300 is formed, the lower redistribution via 320V may have a tapered shape of which horizontal width may increase as a distance from the first semiconductor chip 200 increases.

In some embodiments, the semiconductor package 1000 may further include a lower passivation layer 350. The lower passivation layer 350 may be arranged on a bottom surface of the lower redistribution structure 300 and may serve to protect the lower redistribution structure 300. In some embodiments, the lower passivation layer 350 may be referred to as a lowermost redistribution insulating layer. The lower passivation layer 350 may include an insulating material, for example, a thermosetting resin or a thermoplastic resin. However, the present disclosure is not limited thereto.

For example, at least parts of the lower redistribution lines 320L may be exposed through openings of the lower passivation layer 350. Portions of the lower redistribution lines 320L exposed through the openings may be referred to as lower pads.

In some embodiments, under bump metallurgies (UBMs) 330 may be formed on the lower pads. External connection terminals 340 may be attached to the UBMs 330. However, the present disclosure is not limited thereto, and the external connection terminals 340 may be attached onto the lower pads without the UBMs 330.

The external connection terminals 340 may connect the semiconductor package 1000 to a main board of a separate electronic device on which the semiconductor package 1000 is mounted. The external connection terminals 340 may include at least one of conductive materials, such as, but not limited to, solder, tin (Sn), silver (Ag), copper (Cu), and aluminum (Al). The external connection terminals 340 may have various shapes, such as, but not limited to, a land shape, a bump shape, a pillar shape, or a pin shape, in addition to a ball shape.

The first molding layer ML1 may be positioned between the connection structure 100 and the first semiconductor chip 200 in the cavity 100_C, and may cover top surfaces of the connection structure 100 and the first semiconductor chip 200.

The first molding layer ML1 may include an epoxy-based material, a thermosetting material, or a thermoplastic material. For example, the first molding layer ML1 may include, but not limited to, ABF, FR4, BT, or an epoxy molding compound (EMC).

The upper redistribution structure 400 may be positioned on the first molding layer ML1. The upper redistribution structure 400 may include an upper redistribution pattern 420 and upper redistribution insulating layers 410 surrounding the upper redistribution pattern 420. The upper redistribution pattern 420 may be electrically connected to the connection structure 100.

The upper redistribution pattern 420 may include upper redistribution lines 420L and upper redistribution vias 420V. The upper redistribution lines 420L may extend in the horizontal direction in the upper redistribution insulating layers 410. The upper redistribution vias 420V may extend in the vertical direction (Z direction) from the upper redistribution lines 420L. The upper redistribution pattern 420 may be electrically connected to the via structure 120 of the connection structure 100. For example, the upper redistribution pattern 420 may be electrically connected to the lower redistribution pattern 320 of the lower redistribution structure 300 through the connection structure 100.

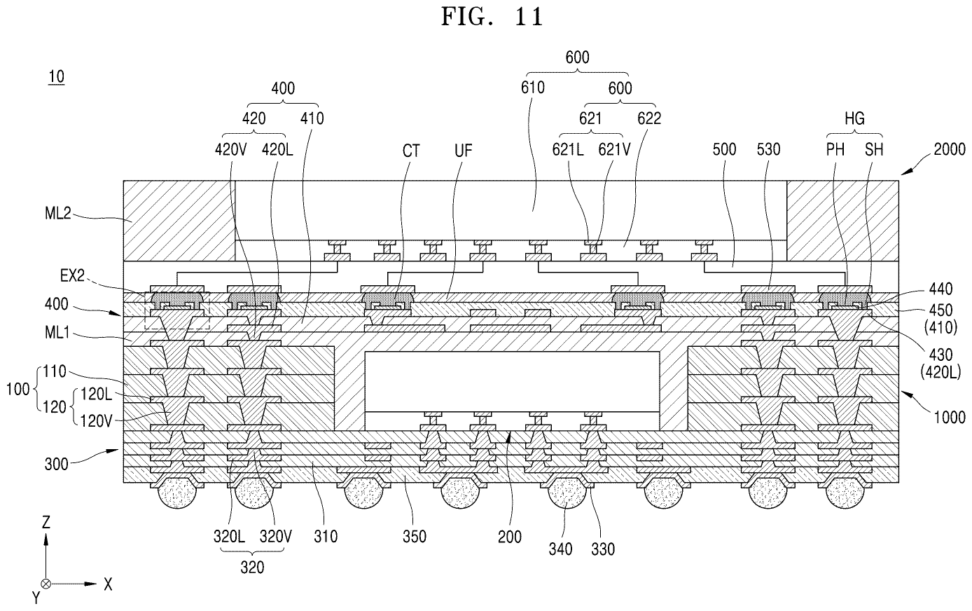

The upper redistribution pattern 420 may include upper pads 430 and metal layers 440. Each of the upper pads 430 may be part of the upper redistribution line 420L at the top of the upper redistribution lines 420L. The upper pads 430 may contact connection terminals (e.g., connection terminals CT of FIG. 11) when a second semiconductor package (e.g., semiconductor package 2000 of FIG. 11) is mounted on the semiconductor package 1000.

The metal layers 440 may be positioned on top surfaces of the upper pads 430, respectively. For example, the metal layers 440 may cover parts of the top surfaces of the upper pads 430, respectively. For example, reactivity of the upper pads 430 may be greater than reactivity of the metal layers 440. The metal layers 440 may have a slower oxidation reaction than the oxidation reaction of the upper pads 430. Accordingly, the metal layers 440 may prevent and/or reduce a possibility of the upper pads 430 from being oxidized.

In some embodiments, a horizontal width of each of the upper pads 430 may be greater than a horizontal width of each of the metal layers 440. For example, the horizontal width of each of the upper pads 430 may be greater than the horizontal width of each of the metal layers 440. For example, the horizontal width of each of the upper pads 430 may exceed the horizontal width of each of the metal layers 440 by about 10 micrometers (μm) to 20 μm. However, the present disclosure is not limited in this regard. For example, side surfaces of each of the metal layers 440 may overlap the top surface of each of the upper pads 430 in the vertical direction (Z direction).

In some embodiments, the upper pads 430 may include a conductive material, such as, but not limited to, copper (Cu), aluminum (Al), silver (Ag), tin (Sn), lead (Pb), titanium (Ti), or an alloy thereof. The metal layers 440 may include, but not be limited to, nickel (Ni), gold (Au), or an alloy thereof.

The upper redistribution insulating layers 410 may include a plurality of layers including an uppermost insulating layer 450 which may surround the upper pads 430 and the metal layers 440. For example, part of the top surface of each of the upper pads 430 may contact each of the metal layers 440, and the other part thereof may contact the uppermost insulating layer 450.

The upper redistribution insulating layers 410 may include an insulating material, for example, a PID resin or an ABF. In this case, the upper redistribution insulating layers 410 may further include an inorganic filler. The upper redistribution insulating layers 410 may include the same material and/or different materials.

The upper redistribution structure 400 may include groove groups HG. The groove groups HG may pass through at least part of the uppermost insulating layer 450. The groove groups HG may overlap the upper pads 430 in the vertical direction (Z direction), respectively. The upper pads 430 and the metal layers 440 may be exposed to the outside through the groove groups HG, respectively.

Each of the groove groups HG may include a pad groove PH and a side groove SH. The pad groove PH may overlap one of the metal layers 440 in the vertical direction (Z direction). The side groove SH may overlap one of the upper pads 430 in the vertical direction (Z direction). The top surfaces of the upper pads 430 may be exposed to the outside through the side groove SH, and top surfaces of the metal layers 440 may be exposed to the outside through the pad groove PH.

In some embodiments, as illustrated in FIG. 1, the side groove SH of each of the groove groups HG may be spaced apart from the pad groove PH of each of the groove groups HG in the horizontal direction. From a two-dimensional perspective, the pad groove PH of each of the groove groups HG may have a circular shape, and the side groove SH of each of the groove groups HG may have a ring shape. The side groove SH of each of the groove groups HG may surround the pad groove PH of each of the groove groups HG. As used herein, a two-dimensional perspective may refer to a perspective looking at the X-Y plane.

Hereinafter, for convenience of description, a first groove group HG_1 as one of the groove groups HG and a first upper pad 430_1 and a first metal layer 440_1 overlapping the first groove group HG_1 in the vertical direction (Z direction) are described with reference to FIG. 3.

The pad groove PH of the first groove group HG_1 may overlap the first metal layer 440_1 in the vertical direction (Z direction). The first metal layer 440_1 may be exposed to the outside through the pad groove PH of the first groove group HG_1. The side groove SH of the first groove group HG_1 may be spaced apart from the pad groove PH of the first groove group HG_1. For example, the side groove SH of the first groove group HG_1 may be spaced apart from the metal layers 440 in the horizontal direction. The side groove SH of the first groove group HG_1 may overlap a portion of the first upper pad 430_1 contacting the uppermost insulating layer 450 in the vertical direction (Z direction). The first upper pad 430_1 may be exposed to the outside through the side groove SH of the first groove group HG_1.

A horizontal width of the pad groove PH of the first groove group HG_1 and a horizontal width of the side groove SH of the first groove group HG_1 may be reduced as the pad groove PH of the first groove group HG_1 and the side groove SH of the first groove group HG_1 are closer to the first upper pad 430_1. For example, the pad groove PH of the first groove group HG_1 and the side groove SH of the first groove group HG_1 may be formed by a photo process, and an internal wall of each of the pad groove PH of the first groove group HG_1 and the side groove SH of the first groove group HG_1 may be inclined.

The internal wall of the side groove SH of the first groove group HG_1 may overlap a top surface of the first upper pad 430_1 in the vertical direction (Z direction), and the internal wall of the pad groove PH of the first groove group HG_1 may overlap a top surface of the first metal layer 440_1 in the vertical direction (Z direction). For example, the horizontal width of the pad groove PH of the first groove group HG_1 may be less (narrower) than a horizontal width of the first metal layer 440_1, such that only the top surface of the first metal layer 440_1 may be exposed to the outside through the pad groove PH of the first groove group HG_1. The side groove SH of the first groove group HG_1 may be spaced apart from the first metal layer 440_1, so that only the top surface of the first upper pad 430_1 may be exposed to the outside through the side groove SH of the first groove group HG_1.

A thickness (e.g., a length in the vertical direction (Z direction)) of the pad groove PH of the first groove group HG_1 may be less than a thickness of the side groove SH of the first groove group HG_1. For example, the pad groove PH of the first groove group HG_1 may extend from a top surface of the uppermost insulating layer 450 to the top surface of the first metal layer 440_1, and the side groove SH of the first groove group HG_1 may extend from the top surface of the uppermost insulating layer 450 to the top surface of the first upper pad 430_1 coplanar with a bottom surface of the first metal layer 440_1.

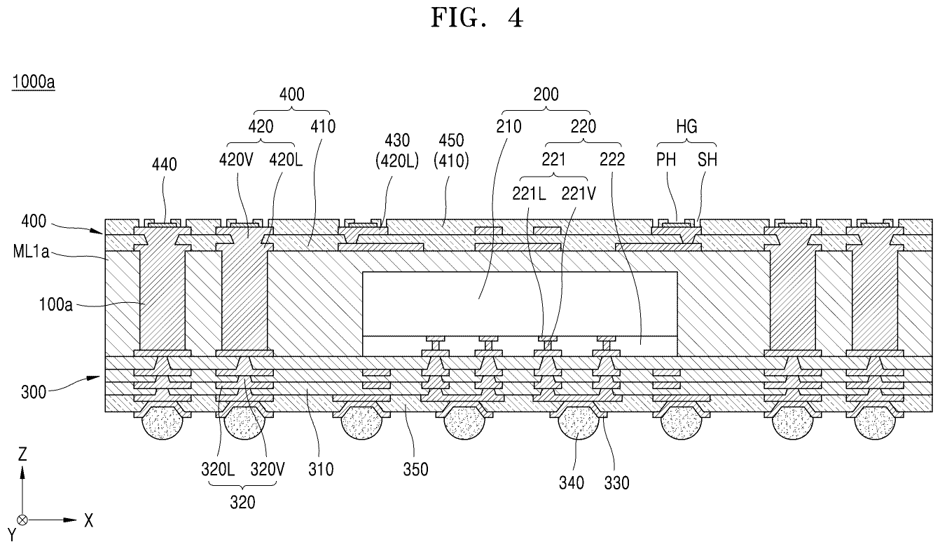

FIG. 4 is a cross-sectional view schematically illustrating a portion of a semiconductor package 1000a cut away, according to embodiments.

The semiconductor package 1000a of FIG. 4 may include and/or may be similar in many respects to the semiconductor package 1000 described above with reference to FIGS. 1 to 3, and may include additional features not mentioned above. Consequently, repeated descriptions of the semiconductor package 1000a described above with reference to FIGS. 1 to 3 may be omitted for the sake of brevity.

Referring to FIG. 4, the semiconductor package 1000a may include a lower redistribution structure 300, a connection structure 100a, a first semiconductor chip 200, a first molding layer ML1a, and an upper redistribution structure 400. For example, the semiconductor package 1000 of FIG. 2 may have a panel-level packaging (PLP) structure, and the semiconductor package 1000a of FIG. 4 may have a wafer-level packaging (WLP) structure.

The lower redistribution structure 300 may extend I/O terminals of the first semiconductor chip 200 to the outside of the first semiconductor chip 200. The first semiconductor chip 200 may be positioned on the lower redistribution structure 300 to be electrically connected to the lower redistribution structure 300. The first molding layer ML1a may be positioned on the lower redistribution structure 300 to surround the first semiconductor chip 200. For example, side surfaces of the first molding layer ML1a may be aligned with side surfaces of the lower redistribution structure 300 in the vertical direction (Z direction).

The connection structure 100a may be electrically connected to the lower redistribution structure 300 through the first molding layer ML1a. For example, the connection structure 100a may be a through mold via (TMV). In an embodiment, the connection structure 100a may contact the upper redistribution structure 400 and the lower redistribution structure 300 and may electrically connect the upper redistribution structure 400 to the lower redistribution structure 300. For example, the connection structure 100a may include a conductive material, such as, but not limited to, copper (Cu), aluminum (Al), silver (Ag), tin (Sn), gold (Au), nickel (Ni), lead (Pb), titanium (Ti), or an alloy thereof.

The upper redistribution structure 400 may be formed on the first molding layer ML1a. Upper redistribution insulating layers 410 of the upper redistribution structure 400 may include a plurality of layers. Side surfaces of the upper redistribution structure 400 may be aligned with the side surfaces of the first molding layer ML1a in the vertical direction (Z direction).

For example, the upper redistribution insulating layers 410 may include an insulating material (e.g., a PID resin). In this case, the upper redistribution insulating layers 410 may further include an inorganic filler. For example, the uppermost insulating layer 450 of the upper redistribution insulating layers 410 and the remaining layers may include a substantially similar and/or the same material. For example, a constituent material of the upper redistribution insulating layers 410 may be different from a constituent material of the first molding layer ML1a.

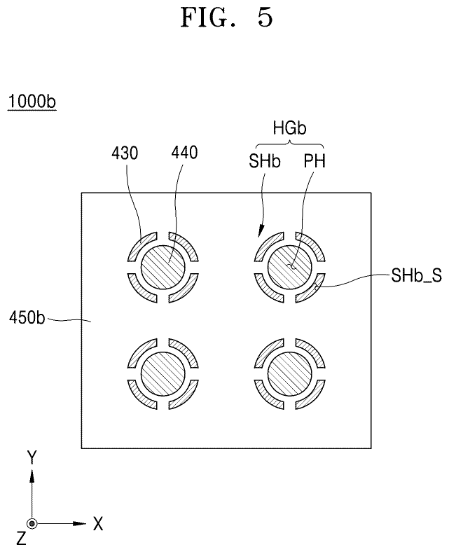

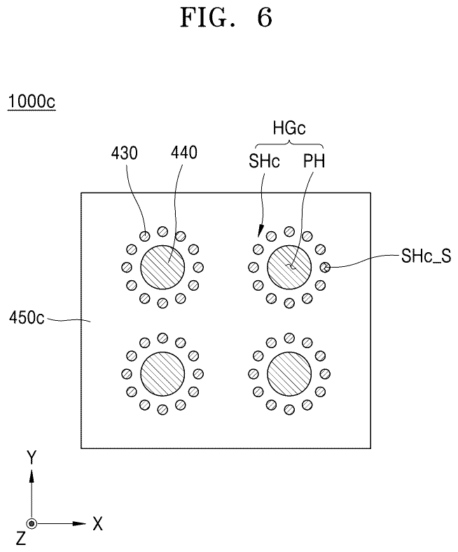

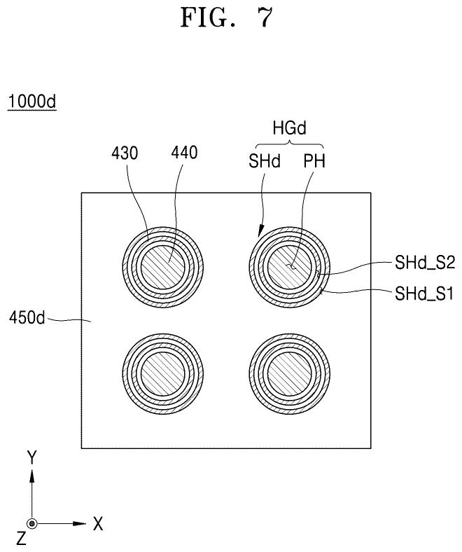

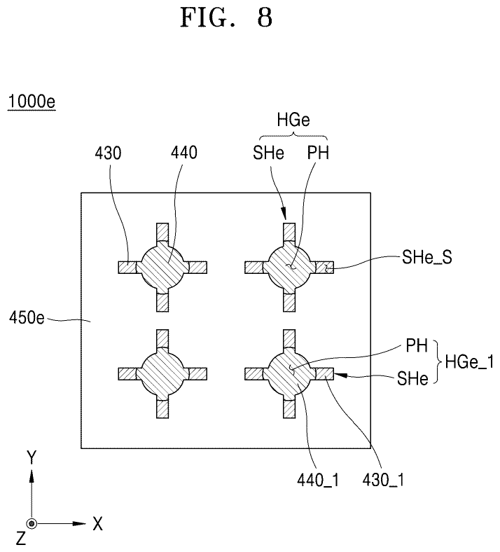

FIG. 5 is a plan view illustrating a portion of a semiconductor package 1000b, according to embodiments. FIG. 6 is a plan view illustrating a portion of a semiconductor package 1000c, according to embodiments. FIG. 7 is a plan view illustrating a portion of a semiconductor package 1000d, according to embodiments. FIG. 8 is a plan view illustrating a portion of a semiconductor package 1000e, according to embodiments.

The semiconductor packages 1000b, 1000c, 1000d, and 1000e of FIGS. 5 to 8 may include and/or may be similar in many respects to the semiconductor package 1000 described above with reference to FIGS. 1 to 3, and may include additional features not mentioned above. Consequently, repeated descriptions of the semiconductor packages 1000b, 1000c, 1000d, and 1000e described above with reference to FIGS. 1 to 3 may be omitted for the sake of brevity. For example, the semiconductor packages 1000b, 1000c, 1000d, and 1000e of FIGS. 5 to 8 illustrate various shapes of the side grooves SH of the groove groups HG in the semiconductor package 1000 of FIG. 1.

Referring to FIG. 5, the uppermost insulating layer 450b of the semiconductor package 1000b may include groove groups HGb. The groove groups HGb may overlap upper pads 430 and metal layers 440 in the vertical direction (Z direction), respectively.

Each of the groove groups HGb may include a pad groove PH and a side groove SHb. The pad groove PH of each of the groove groups HGb may overlap one of the metal layers 440 in the vertical direction (Z direction), and the side groove SHb of each of the groove groups HGb may overlap one of the upper pads 430 in the vertical direction (Z direction). Part of each of the upper pads 430 may be exposed to the outside by the side groove SHb of each of the groove groups HGb, and part of each of the metal layers 440 may be exposed to the outside by the pad groove PH of each of the groove groups HGb.

The side groove SHb of each of the groove groups HGb may include a plurality of sub-grooves SHb_S. For example, the plurality of sub-grooves SHb_S may be spaced apart from one another in the horizontal direction. The plurality of sub-grooves SHb_S of the side groove SHb of each of the groove groups HGb may be arranged to surround the pad groove PH of each of the groove groups HGb.

In some embodiments, the pad grooves PH of each of the groove groups HGb may have a circular shape, and each of the plurality of sub-grooves SHb_S may extend in a circumferential direction of the pad groove PH. The plurality of sub-grooves SHb_S may be spaced apart from one another in the circumferential direction of the pad groove PH. For example, each of the plurality of sub-grooves SHb_S may have an arc shape, and the plurality of sub-grooves SHb_S may be arranged to have a broken ring shape.

Referring to FIG. 6, the uppermost insulating layer 450c of the semiconductor package 1000c may include groove groups HGc. The groove groups HGc may overlap upper pads 430 and metal layers 440 in the vertical direction (Z direction), respectively.

Each of the groove groups HGc may include a pad groove PH and a side groove SHc. The pad groove PH of each of the groove groups HGc may overlap one of the metal layers 440 in the vertical direction (Z direction), and the side groove SHc of each of the groove groups HGc may overlap one of the upper pads 430 in the vertical direction (Z direction).

The side groove SHc of each of the groove groups HGc may include a plurality of sub-grooves SHc_S. For example, the plurality of sub-grooves SHc_S may be spaced apart from one another in the horizontal direction. The plurality of sub-grooves SHc_S of the side groove SHc of each of the groove groups HGc may be arranged to surround the pad groove PH of each of the groove groups HGc.

In some embodiments, the pad groove PH of each of the groove groups HGc may have a circular shape from a two-dimensional perspective. From a two-dimensional perspective, each of the plurality of sub-grooves SHc_S of the side groove SHc of each of the groove groups HGc may have a circular shape. The plurality of sub-grooves SHc_S may be spaced apart from one another in a circumferential direction of the pad groove PH. Although FIG. 6 illustrates each of the plurality of sub-grooves SHc_S as having a circular shape, the present disclosure is not limited in this regard. For example, each of the plurality of sub-grooves SHc_S may have a polygonal shape.

Referring to FIG. 7, the uppermost insulating layer 450d of the semiconductor package 1000d may include groove groups HGd. The groove groups HGd may overlap upper pads 430 and metal layers 440 in the vertical direction (Z direction), respectively.

Each of the groove groups HGd may include a pad groove PH and a side groove SHd. The pad groove PH of each of the groove groups HGd may overlap one of the metal layers 440 in the vertical direction (Z direction), and the side groove SHd of each of the groove groups HGd may overlap one of the upper pads 430 in the vertical direction (Z direction).

The side groove SHd of each of the groove groups HGd may include a first sub-groove SHd_S1 and a second sub-groove SHd_S2. Each of the first sub-groove SHd_S1 and the second sub-groove SHd_S2 of the side groove SHd of each of the groove groups HGd may be spaced apart from the pad groove PH of each of the groove groups HGd in the horizontal direction. Each of the first sub-groove SHd_S1 and the second sub-groove SHd_S2 of the side groove SHd of each of the groove groups HGd may surround the pad groove PH of each of the groove groups HGd. For example, from a two-dimensional perspective, each of the first sub-groove SHd_S1 and the second sub-groove SHd_S2 may have a ring shape.

A distance between the first sub-groove SHd_S1 and the pad groove PH may be greater than a distance between the second sub-groove SHd_S2 and the pad groove PH. In this case, the pad groove PH may be included in the same groove group as the groove group including the first sub-groove SHd_S1 and the second sub-groove SHd_S2. For example, the first sub-groove SHd_S1 may surround the second sub groove SHd_S2 and the pad groove PH included in the same groove group. Although FIG. 7 illustrates the side groove SHd as surrounding the pad groove PH of the same groove group with two sub-grooves, the present disclosure is not limited in this regard. That is, the number of sub-grooves included in the side groove SHd is not limited thereto.

Referring to FIG. 8, the uppermost insulating layer 450e of the semiconductor package 1000e may include groove groups HGe. The groove groups HGe may overlap upper pads 430 and metal layers 440 in the vertical direction (Z direction), respectively.

Each of the groove groups HGe may include a pad groove PH and a side groove SHe. The pad groove PH of each of the groove groups HGe may overlap one of the metal layers 440 in the vertical direction (Z direction), and the side groove SHe of each of the groove groups HGe may overlap one of the upper pads 430 in the vertical direction (Z direction).

The side groove SHe may include a plurality of sub-grooves SHe_S. The plurality of sub-grooves SHe_S may communicate with the pad groove PH of the same groove group. For example, internal walls of the plurality of sub-grooves SHe_S may contact an internal wall of the pad groove PH. Although FIG. 8 illustrates the side groove SHe of each of the groove groups HGe as including four sub-grooves, the present disclosure is not limited in this regard. That is, the number and arrangement of sub-grooves included in the side groove SHe are not limited thereto.

For convenience of description, the first groove group GHe_1 from among the groove groups HGe and the first upper pad 430_1 and the first metal layer 440_1 overlapping the first groove group GHe_1 in the vertical direction (Z direction) are described. The pad groove PH of the first groove group GHe_1 may expose a portion of the top surface of the first metal layer 440_1 to the outside. The side groove SHe of the first groove group GHe_1 may expose a portion of the top surface of the first metal layer 440_1 and a portion of the top surface of the first upper pad 430_1 to the outside. For example, some of side surfaces of the first metal layer 440_1 may overlap the side groove SHe of the first groove group GHe_1 in the vertical direction (Z direction).

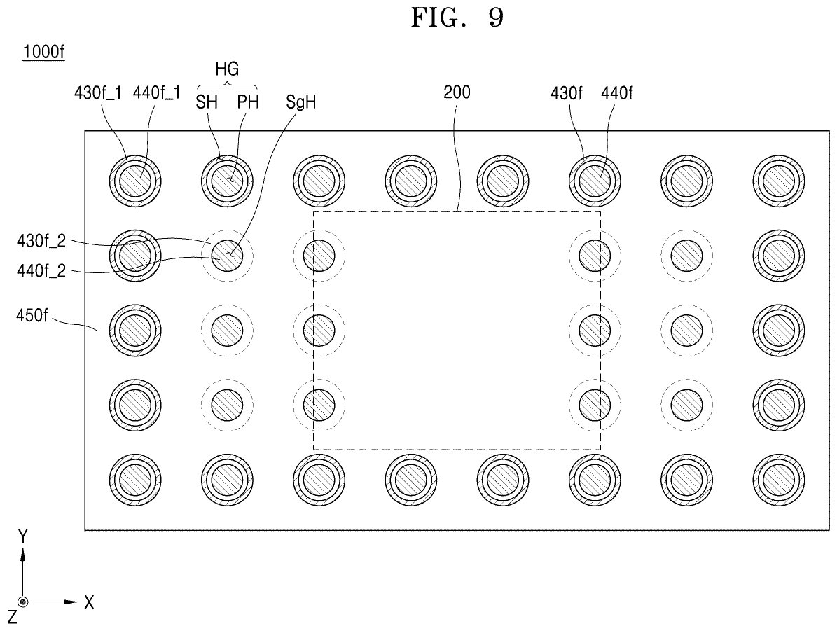

FIG. 9 is a plan view schematically illustrating a semiconductor package 1000f, according to embodiments.

The semiconductor package 1000f of FIG. 9 may include and/or may be similar in many respects to the semiconductor packages 1000, 1000a, 1000b, 1000c, 1000d, and 1000e described above with reference to FIGS. 1 to 8, and may include additional features not mentioned above. Consequently, repeated descriptions of the semiconductor package 1000f described above with reference to FIGS. 1 to 8 may be omitted for the sake of brevity.

An upper redistribution structure 400 of the semiconductor package 1000f may include upper pads 430f and metal layers 440f. The upper redistribution structure 400 may include groove groups HG and single grooves SgH. The groove groups HG may be spaced apart from the single grooves SgH in the horizontal direction. The groove groups HG and the single grooves SgH may be positioned on the upper pads 430f, respectively.

Each of the groove groups HG and the single grooves SgH may extend inward from a top surface of the uppermost insulating layer 450f. For example, each of the groove groups HG may include a pad groove PH and a side groove SH. Each of the single grooves SgH may include one groove. For example, each of the single grooves SgH may be substantially similar and/or the same as the pad groove PH of each of the groove groups HG.

The upper pads 430f may overlap the groove groups HG or the single grooves SgH in the vertical direction (Z direction). For example, parts of top surfaces of the upper pads 430f overlapping the groove groups HG in the vertical direction (Z direction) from among the upper pads 430f may be exposed to the outside. Top surfaces of the upper pads 430f overlapping the single grooves SgH in the vertical direction (Z direction) from among the upper pads 430f may not be exposed to the outside.

In some embodiments, the upper pads 430f may include a first upper pad 430f_1 and a second upper pad 430f_2. The metal layers 440f may include a first metal layer 440f_1 and a second metal layer 440f_2. The first metal layer 440f_1 may overlap the first upper pad 430f_1 in the vertical direction (Z direction), and the second metal layer 440f_2 may overlap the second upper pad 430f_2 in the vertical direction (Z direction).

The first upper pad 430f_1 may overlap one of the groove groups HG in the vertical direction (Z direction). The second upper pad 430f_2 may overlap one of the single grooves SgH in the vertical direction (Z direction). Part of a top surface of the first upper pad 430f_1 may be exposed to the outside by the side groove SH of one of the groove groups HG, and a top surface of the second upper pad 430f_2 may be completely covered with the uppermost insulating layer 450f and the second metal layer 440f_2. For example, the single groove overlapping the second upper pad 430f_2 in the vertical direction (Z direction) may be positioned on the second metal layer 440f_2, so that part of a top surface of the second metal layer 440f_2 may be exposed to the outside.

In some embodiments, the first upper pad 430f_1 may be closer to a side surface of the uppermost insulating layer 450f than the second upper pad 430f_2. For example, the second upper pad 430f_2 may be positioned in a central region of the uppermost insulating layer 450f, and the first upper pad 430f_1 may be positioned in an edge region surrounding the central region of the uppermost insulating layer 450f. An outermost upper pad from among the upper pads 430f may be exposed to the outside by the groove groups HG, and an internal upper pad from among the upper pads 430f may not be exposed to the outside.

A warpage phenomenon in which the semiconductor package 1000f is bent may occur during the manufacturing process of the semiconductor package 1000f. Subsequently, in a process of stacking a second semiconductor package (e.g., semiconductor package 2000 of FIG. 11) on the semiconductor package 1000f, a phenomenon in which connection terminals (e.g., connection terminals CT of FIG. 11) contact one another may occur due to the warpage phenomenon. For example, the groove groups HG may be formed on the upper pad 430f on which the connection terminals CT relatively deformed by the warpage phenomenon are positioned, for example, the outermost upper pad 430f to prevent the connection terminals CT from contacting adjacent connection terminals.

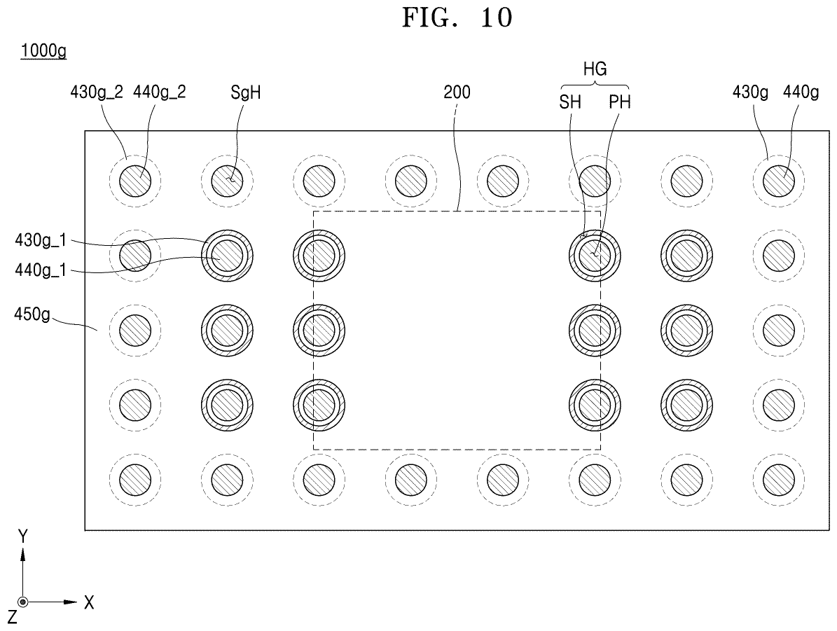

FIG. 10 is a plan view schematically illustrating a semiconductor package 1000g, according to embodiments.

The semiconductor package 1000g of FIG. 10 may include and/or may be similar in many respects to the semiconductor packages 1000, 1000a, 1000b, 1000c, 1000d, 1000e, and 1000f described above with reference to FIGS. 1 to 9, and may include additional features not mentioned above. Consequently, repeated descriptions of the semiconductor package 1000g described above with reference to FIGS. 1 to 9 may be omitted for the sake of brevity.

When the warpage phenomenon occurs in each of the semiconductor packages 1000f and 1000g of FIGS. 9 and 10, the semiconductor package 1000g of FIG. 10 and the semiconductor package 1000f of FIG. 9 may have different bending directions from each other, so that positions of the groove groups HG of the semiconductor package 1000f of FIG. 9 may be different from positions of the groove groups HG of the semiconductor package 1000g of FIG. 10.

The semiconductor package 1000g may include groove groups HG and single grooves SgH. Upper pads 430g may include a first upper pad 430g_1 and a second upper pad 430g_2, and metal layers 440g may include a first metal layer 440g_1 and a second metal layer 440g_2. Each of the groove groups HG may be positioned on the first upper pad 430g_1. Each of the single grooves SgH may be positioned on the second upper pad 430g_2. The first upper pad 430g_1 may be exposed to the outside by a pad groove PH of each of the groove groups HG, and the first metal layer 440g_1 may be exposed to the outside by a side groove SH of each of the groove groups HG. The second upper pad 430g_2 may not be exposed to the outside, and the second metal layer 440g_2 may be exposed to the outside by each of the single grooves SgH.

In some embodiments, the second upper pad 430g_2 may be closer to a side surface of the uppermost insulating layer 450g than the first upper pad 430g_1. For example, the first upper pad 430g_1 may be positioned in a central region of the uppermost insulating layer 450g, and the second upper pad 430g_2 may be positioned in an edge region surrounding the central region of the uppermost insulating layer 450g. An outermost upper pad from among the upper pads 430g may be exposed to the outside by the groove groups HG, and an internal upper pad from among the upper pads 430g may not be exposed to the outside.

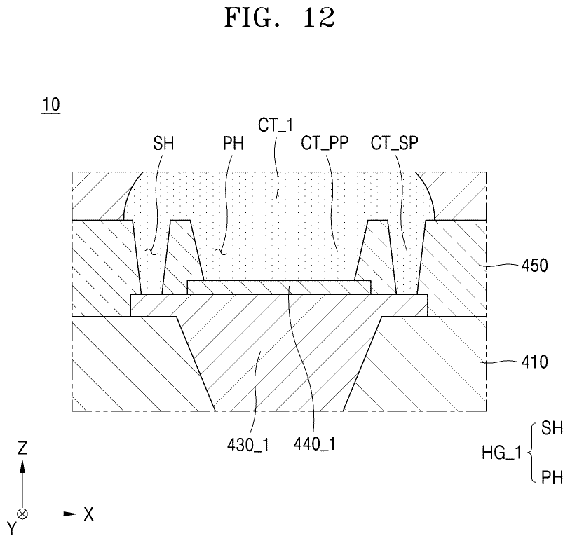

FIG. 11 is a cross-sectional view schematically illustrating a portion of a semiconductor package 10 cut away, according to embodiments. FIG. 12 is an enlarged view schematically illustrating the semiconductor package 10 of FIG. 11 by enlarging the portion EX2 of FIG. 11.

Referring to FIGS. 11 and 12, the semiconductor package 10 may include a first semiconductor package 1000, connection terminals CT, and a second semiconductor package 2000. For example, the semiconductor package 10 may have a package-on-package (PoP) structure. The second semiconductor package 2000 may be referred to as an upper semiconductor package, and the first semiconductor package 1000 may be referred to as a lower semiconductor package.

The semiconductor packages 1000 and 2000 of FIGS. 11 and 12 may include and/or may be similar in many respects to the semiconductor packages 1000, 1000a, 1000b, 1000c, 1000d, 1000e, 1000f, and 1000g described above with reference to FIGS. 1 to 10, and may include additional features not mentioned above. Consequently, repeated descriptions of the semiconductor packages 1000 and 2000 described above with reference to FIGS. 1 to 10 may be omitted for the sake of brevity.

The first semiconductor package 1000 may include a lower redistribution structure 300, a first semiconductor chip 200, a first molding layer ML1, an upper redistribution structure 400, and a connection structure 100.

The upper redistribution structure 400 may include an upper redistribution pattern 420 and upper redistribution insulating layers 410. The upper redistribution pattern 420 may include upper pads 430 and metal layers 440 positioned on the upper pads 430. The upper redistribution insulating layers 410 may include an uppermost insulating layer 450 surrounding the upper pads 430 and the metal layers 440. The uppermost insulating layer 450 may include groove groups HG passing through at least part of the uppermost insulating layer 450. Each of the groove groups HG may include a pad groove PH overlapping one of the upper pads 430 in the vertical direction (Z direction) and a side groove SH overlapping one of the metal layers 440 in the vertical direction (Z direction).

The second semiconductor package 2000 may include a package substrate 500, a second semiconductor chip 600, and a second molding layer ML2. In some embodiments, the second semiconductor package 2000 may include only the second semiconductor chip 600 without the package substrate 500 and the second molding layer ML2. For example, when the second semiconductor package 2000 includes only the second semiconductor chip 600, the connection terminals CT may be attached onto a bottom surface of the second semiconductor chip 600.

The package substrate 500 may be a printed circuit board (PCB) including a core insulating layer. The core insulating layer may generally have a flat plate shape or a panel shape. The core insulating layer may include top and bottom surfaces opposite to each other, and the top and bottom surfaces of the core insulating layer may be flat.

For example, the core insulating layer may include, but not be limited to, at least one of prepreg, polyimide, FR4, tetrafunctional epoxy, polyphenylene ether, epoxy/polyphenylene oxide, BT, thermount, cyanate ester, a liquid crystal polymer, or the like.

The package substrate 500 may further include an upper pad PS_P positioned on a top surface of the core insulating layer. In some embodiments, the upper pad PS_P may be electrically connected by internal wiring. In some embodiments, the package substrate 500 may further include a lower pad 530 positioned on a bottom surface of the core insulating layer. The lower pad 530 may be electrically connected to the upper pad PS_P by a through via and/or the internal wiring. For example, each of the upper pad PS_P and the lower pad 530 may include copper (Cu), nickel (Ni), stainless steel, or beryllium copper.

In some embodiments, the package substrate 500 may be and/or may include an interposer such as, but not limited to, a glass interposer or a silicon interposer.

The second semiconductor chip 600 may be positioned on the package substrate 500. The second semiconductor chip 600 may include a second semiconductor substrate 610 and a second wiring structure 620. The second semiconductor substrate 610 may include an active surface and an inactive surface opposite thereto. The second wiring structure 620 may be formed on the active surface of the second semiconductor substrate 610.

The second semiconductor chip 600 may be arranged on the package substrate 500 such that the active surface of the second semiconductor substrate 610 faces the first semiconductor package 1000. For example, the second semiconductor chip 600 may be arranged on the package substrate 500 in a face-down manner.

The second semiconductor substrate 610 may include, for example, a semiconductor material such as, but not limited to, silicon (Si) or germanium (Ge). Alternatively or additionally, the second semiconductor substrate 610 may include a compound semiconductor material such as, but not limited to, silicon carbide (SiC), gallium arsenide (GaAs), indium arsenide (InAs), or indium phosphide (InP). The second semiconductor substrate 610 may include a well doped with impurities as a conductive region. The second semiconductor substrate 610 may have various device isolation structures such as, but not limited to, a shallow trench isolation (STI) structure.

A plurality of various types of individual devices may be formed on the active surface of the second semiconductor substrate 610. The plurality of individual devices may be electrically connected to the second wiring structure 620. In addition, each of the plurality of individual devices may be electrically isolated from other adjacent individual devices by an insulating layer.

In some embodiments, the second semiconductor chip 600 may include a logic device. For example, the second semiconductor chip 600 may be and/or may include a CPU chip, a GPU chip, an AP chip, or the like. In other embodiments, when the semiconductor package includes a plurality of second semiconductor chips 600, at least one of the plurality of second semiconductor chips 600 may be and/or may include a CPU chip, a GPU chip, an AP chip, or the like. In some embodiments, the plurality of second semiconductor chips 600 may also include a memory semiconductor chip including a memory device.

For example, the memory device may be and/or may include a non-volatile memory device such as, but not limited to, flash memory, PRAM, MRAM, FeRAM, RRAM, or the like. In some embodiments, the memory device may be and/or may include a volatile memory device such as, but not limited to, DRAM or SRAM.

The second wiring structure 620 of the second semiconductor chip 600 may include second wiring patterns 621 and a second wiring insulating layer 622 surrounding the second wiring patterns 621. Each of the second wiring patterns 621 may include a second wiring line 621L extending in the horizontal direction and a second wiring via 621V extending in the vertical direction (Z direction) from the second wiring line 621L. The second wiring patterns 621 may be electrically connected to the plurality of individual devices of the second semiconductor substrate 610.

The connection terminals CT may be positioned between the first semiconductor package 1000 and the second semiconductor package 2000. In an embodiment, the connection terminals CT may physically and electrically connect the first semiconductor package 1000 to the second semiconductor package 2000. For example, the connection terminals CT may include at least one of conductive materials, for example, solder, tin (Sn), silver (Ag), copper (Cu), aluminum (Al), or the like.

The connection terminals CT may be positioned on the upper redistribution structure 400 of the first semiconductor package 1000. The connection terminals CT may contact the upper pads 430 and the metal layers 440 of the upper redistribution structure 400 of the first semiconductor package 1000.

Each of the connection terminals CT may be positioned in the pad groove PH and the side groove SH of each of the groove groups HG. Each of the connection terminals CT may include a pad protrusion CT_PP and a side protrusion CT_SP. The pad protrusion CT_PP of each of the connection terminals CT may be positioned in the pad groove PH of one of the groove groups HG, and may contact one of the metal layers 440. The side protrusion CT_SP of each of the connection terminals CT may be positioned in the side groove SH of one of the groove groups HG, and may contact one of the upper pads 430.

In some embodiments, in a process of stacking the second semiconductor package 2000 on the first semiconductor package 1000, the connection terminals CT may be pressed in the vertical direction (Z direction), so that each of the connection terminals CT may fill the side groove SH and the pad groove PH of each of the groove groups HG. Each of the connection terminals CT fills the side groove SH and the pad groove PH of each of the groove groups HG, so that contact between the connection terminals CT may be suppressed.

Hereinafter, for convenience of description, a first connection terminal CT_1 as one of the connection terminals CT, a first upper pad 430_1, a first metal layer 440_1, and a first groove group HG_1 are described with reference to FIG. 12.

The first upper pad 430_1, the first metal layer 440_1, and the first connection terminal CT_1 may overlap one another in the vertical direction (Z direction). The side groove SH of the first groove group HG_1 may overlap the first upper pad 430_1 in the vertical direction (Z direction), and the pad groove PH of the first groove group HG_1 may overlap the first metal layer 440_1 in the vertical direction (Z direction).

The first connection terminal CT_1 may include a pad protrusion CT_PP and a side protrusion CT_SP. The pad protrusion CT_PP of the first connection terminal CT_1 may be positioned in the pad groove PH of the first groove group HG_1, and the side protrusion CT_SP of the first connection terminal CT_1 may be positioned in the side groove SH of the first groove group HG_1. The pad protrusion CT_PP of the first connection terminal CT_1 may be positioned in the pad groove PH of the first groove group HG_1, and the side protrusion CT_SP of the first connection terminal CT_1 may be positioned in the side groove SH of the first groove group HG_1.

The pad protrusion CT_PP of the first connection terminal CT_1 may contact the first metal layer 440_1, and the side protrusion part CT_SP of the first connection terminal CT_1 may be spaced apart from the first metal layer 440_1 and may contact the first upper pad 430_1. The side protrusion CT_SP of the first connection terminal CT_1 and the pad protrusion CT_PP of the first connection terminal CT_1 may be spaced apart from each other in the horizontal direction with the uppermost insulating layer 450 therebetween.

In some embodiments, a horizontal width of the first metal layer 440_1 may be less than a horizontal width of the first upper pad 430_1. Part of the top surface of the first upper pad 430_1 may contact the first metal layer 440_1, another part of the top surface of the first upper pad 430_1 may contact the side protrusion CT_SP of the first connection terminal CT_1, and the remaining part of the top surface of the first upper pad 430_1 may contact the uppermost insulating layer 450.

In some embodiments, the side protrusion CT_SP of the first connection terminal CT_1 may be spaced apart from the pad protrusion CT_PP of the first connection terminal CT_1 in the horizontal direction. The side protrusion CT_SP of the first connection terminal CT_1 may surround the pad protrusion CT_PP of the first connection terminal CT_1. For example, a cross-section of the pad protrusion CT_PP of the first connection terminal CT_1 may have a circular shape, and a cross-section of the side protrusion CT_SP of the first connection terminal CT_1 may have a ring shape. For example, the shape of the pad protrusion CT_PP of the first connection terminal CT_1 may correspond to the shape of the pad groove PH of the first groove group, and the shape of the side protrusion CT_SP of the first connection terminal CT_1 may correspond to the shape of the side groove SH of the first groove group.

In some embodiments, a vertical level of a bottom surface of the side protrusion CT_SP of the first connection terminal CT_1 may be lower than a vertical level of a bottom surface of the pad protrusion CT_PP of the first connection terminal CT_1. For example, the bottom surface of the side protrusion CT_SP of the first connection terminal CT_1 may be coplanar with the top surface of the first upper pad 430_1, and the bottom surface of the pad protrusion CT_PP of the first connection terminal CT_1 may be coplanar with the top surface of the first metal layer 440_1 positioned on the top surface of the first upper pad 430_1. As used herein, the vertical level may refer to a distance from the top surface of the lower redistribution structure 300.

In some embodiments, the semiconductor package 10 may further include an underfill layer UF. The underfill layer UF may be positioned between the first semiconductor package 1000 and the second semiconductor package 2000, and may surround the connection terminals CT. The underfill layer UF may protect the connection terminals CT from the outside. For example, the underfill layer UF may include an insulating polymer such as an epoxy polymer.

The second molding layer ML2 may be positioned on the package substrate 500 and may surround the second semiconductor chip 600. In some embodiments, the second molding layer ML2 may include, but not be limited to, an epoxy-based material, a thermosetting material, or a thermoplastic material. For example, the second molding layer ML2 may include, but not be limited to, ABF, FR4, BT, or an EMC.

While the present disclosure has been particularly shown and described with reference to embodiments thereof, it is to be understood that various changes in form and details may be made therein without departing from the spirit and scope of the following claims.

What is claimed is:

1. A semiconductor package, comprising:
a semiconductor chip;
a molding layer at least partially surrounding the semiconductor chip; and
a redistribution structure on the molding layer and comprising a redistribution pattern and a redistribution insulating layer at least partially surrounding the redistribution pattern,
wherein the redistribution pattern comprises pads and metal layers disposed on the pads,
wherein the redistribution insulating layer comprises:
an uppermost insulating layer at least partially surrounding the pads and the metal layers; and
groove groups at least partially passing through the uppermost insulating layer,
wherein the groove groups at least partially overlap the pads in a vertical direction, respectively,
wherein each of the groove groups comprises a pad groove and a side groove,
wherein the pad groove at least partially overlaps at least one of the metal layers in the vertical direction, and
wherein the side groove at least partially overlaps at least one of the pads in the vertical direction.

2. The semiconductor package of claim 1, wherein a width of each of the pads is greater than a width of each of the metal layers,
wherein a first portion of a top surface of each of the pads is in contact with each of the metal layers, respectively, and
wherein a second portion of the top surface of each of the pads is in contact with the uppermost insulating layer.

3. The semiconductor package of claim 2, wherein the top surface of at least one of the pads is exposed to an outside through the side groove of each of the groove groups, and
wherein a top surface of at least one of the metal layers is exposed to the outside through the pad groove of each of the groove groups.

4. The semiconductor package of claim 1, wherein the side groove of each of the groove groups is spaced apart in a horizontal direction from the pad groove of a same groove group.

5. The semiconductor package of claim 4, wherein a top surface of the pad groove of each of the groove groups has a circular shape, and
wherein the side groove of each of the groove groups has a ring shape at least partially surrounding the pad groove of the same groove group.

6. The semiconductor package of claim 4, wherein the side groove of each of the groove groups comprises a first sub-groove and a second sub-groove,
wherein the first sub-groove and the second sub-groove of the side groove of each of the groove groups are spaced apart in the horizontal direction from the pad groove of the same groove group to at least partially surround the pad groove of the same groove group, and
wherein a distance between the first sub-groove and the pad groove is greater than a distance between the second sub-groove and the pad groove.

7. The semiconductor package of claim 4, wherein the side groove of each of the groove groups comprises sub-grooves spaced apart from one another in the horizontal direction, and
wherein each of the sub-grooves of the side groove of each of the groove groups is disposed to at least partially surround the pad groove of the same groove group.

8. The semiconductor package of claim 1, wherein the side groove of each of the groove groups comprises sub-grooves,
wherein each of the sub-grooves of the side groove of each of the groove groups is coupled with the pad groove of a same groove group, and
wherein each of the sub-grooves at least partially vertically overlaps a metal layer at least partially vertically overlapping the pad groove of the same groove group.

9. The semiconductor package of claim 1, wherein a depth of the side groove of each of the groove groups is greater than a depth of the pad groove of a same groove group.

10. The semiconductor package of claim 1, wherein the pads comprise a first pad and a second pad,
wherein the metal layers comprise a first metal layer positioned on the first pad, and a second metal layer positioned on the second pad,
wherein a portion of a top surface of the first pad is exposed to an outside through at least one of the groove groups, and
wherein a top surface of the second pad is covered by the second metal layer and the uppermost insulating layer.

11. The semiconductor package of claim 10, wherein the first pad is closer to a side surface of the uppermost insulating layer than the second pad.

12. The semiconductor package of claim 10, wherein the second pad is closer to a side surface of the uppermost insulating layer than the first pad.

13. A semiconductor package, comprising:
a first semiconductor package comprising:
a lower redistribution structure;
a first semiconductor chip disposed on the lower redistribution structure;
a first molding layer on the lower redistribution structure and at least partially surrounding the first semiconductor chip;
an upper redistribution structure on the first molding layer; and
a connection structure passing through the first molding layer and coupling the lower redistribution structure with the upper redistribution structure;
a second semiconductor package stacked on the first semiconductor package; and
connection terminals between the first semiconductor package and the second semiconductor package,
wherein the upper redistribution structure comprises:
an upper redistribution pattern comprising upper pads and metal layers positioned on the upper pads; and
an upper redistribution insulating layer comprising an uppermost insulating layer at least partially surrounding the upper pads and the metal layers,
wherein the uppermost insulating layer comprises groove groups passing through at least part of the uppermost insulating layer and at least partially overlapping the upper pads and the metal layers in a vertical direction,
wherein each of the groove groups comprises a side groove at least partially overlapping at least one of the upper pads, and a pad groove at least partially overlapping at least one of the metal layers, and
wherein each of the connection terminals is disposed in the pad groove and the side groove of each of the groove groups.

14. The semiconductor package of claim 13, wherein each of the connection terminals comprises a side protrusion and a pad protrusion disposed in the uppermost insulating layer,
wherein the pad protrusion of each of the connection terminals is disposed in the pad groove of at least one of the groove groups and is in contact with at least one of the metal layers, and
wherein the side protrusion of each of the connection terminals is disposed in the side groove of the at least one of the groove groups and is in contact with at least one of the upper pads.

15. The semiconductor package of claim 14, wherein a horizontal width of each of the upper pads is greater than a horizontal width of each of the metal layers,
wherein a first portion of a top surface of each of the upper pads is in contact with at least one of the metal layers,
wherein a second portion of the top surface of each of the upper pads is in contact with the side protrusion of each of the connection terminals, and
wherein a remaining portion of the top surface of each of the upper pads is in contact with the uppermost insulating layer.

16. The semiconductor package of claim 15, wherein the side protrusion of each of the connection terminals is spaced apart from each of the metal layers.

17. The semiconductor package of claim 14, wherein the side protrusion of each of the connection terminals is spaced apart from the pad protrusion in a horizontal direction and at least partially surrounds the pad protrusion.

18. The semiconductor package of claim 14, wherein a vertical level of a bottom surface of the side protrusion of each of the connection terminals is lower than a vertical level of a bottom surface of the pad protrusion of each of the connection terminals.

19. A semiconductor package, comprising:
a first semiconductor package comprising:
a lower redistribution structure;
a first semiconductor chip disposed on the lower redistribution structure;
a first molding layer on the lower redistribution structure and at least partially surrounding the first semiconductor chip;
an upper redistribution structure on the first molding layer; and
a connection structure passing through the first molding layer and coupling the lower redistribution structure with the upper redistribution structure;
a second semiconductor package stacked on the first semiconductor package; and
connection terminals positioned between the first semiconductor package and the second semiconductor package,
wherein each of the connection terminals comprises a pad protrusion and a side protrusion,
wherein the upper redistribution structure of the first semiconductor package comprises:
an upper redistribution pattern comprising upper pads and metal layers positioned on the upper pads; and
an upper redistribution insulating layer comprising an uppermost insulating layer at least partially surrounding the upper pads and the metal layers,
wherein the pad protrusion of each of the connection terminals passes through the uppermost insulating layer and is in contact with at least one of the upper pads,
wherein the side protrusion of each of the connection terminals passes through the uppermost insulating layer and is in contact with at least one of the metal layers, and
wherein a vertical level of a bottom surface of the side protrusion of each of the connection terminals is lower than a vertical level of a bottom surface of the pad protrusion of each of the connection terminals.

20. The semiconductor package of claim 19, wherein the side protrusion of each of the connection terminals and the pad protrusion of each of the connection terminals are spaced apart from each other in a horizontal direction with the uppermost insulating layer therebetween, and
wherein the side protrusion of each of the connection terminals is spaced apart from each of the metal layers.
